(19) United States
(12) Patent Application Publication
(10) Pub. No.: US 2007/0210449 A1
(43) Pub. Date: Sep. 13, 2007

(54) Memory device and an array of conductive lines and methods of making the same

(76) Inventors: Dirk Caspary, Dresden (DE); Stefano Parascandola, Dresden (DE)

Correspondence Address: EDELL, SHAPIRO & FINNAN, LLC, 1901 RESEARCH BLVD., SUITE 400, ROCKVILLE, MD, 20850, US

(21) Appl. No.: 11/369,013

(22) Filed: Mar. 7, 2006

(51) Int. Cl. H01L 23/48

(52) U.S. Cl. 257/734

(57) ABSTRACT

An array of conductive lines is formed on or at least partially in a semiconductor substrate. The array includes a number of conductive lines extending in a first direction, a number of landing pads made of a conductive material, with individual landing pads being connected to corresponding ones of the conductive lines, wherein the conductive lines include first and second subsets of conductive lines. The conductive lines of the first subset alternate with the conductive lines of the second subset, wherein the landing pads connected to the conductive lines of the first subset are disposed on a first side of the conductive lines, and the landing pads connected to the conductive lines of the second subset are disposed on a second side of the conductive lines, the first side being opposite to the second side.

### FIELD OF THE INVENTION

This invention relates to a memory device and an array of conductive lines and methods for making such a memory device and an array.

### BACKGROUND

Semiconductor memory devices typically comprise arrays of memory cells that are arranged in rows and columns. The gate electrodes of rows of memory cell transistors are connected by word lines, by which the memory cells are addressed. The word lines usually are formed by patterning a conductive layer stack so as to form single word lines which are arranged in parallel. The word lines are electrically insulated from one another laterally by a dielectric material. The lateral distance between two word lines and the width of a word line sum to the pitch of the array of word lines. The pitch is the dimension of the periodicity of a periodic pattern arrangement. The word lines succeed one another in a completely periodic fashion to reduce the required device area as much as possible. Likewise, the bit lines are formed by patterning a conductive layer so as to form the single bit lines.

An example of a non-volatile memory device is based on the NROM technology. FIG. 1A shows a cross-sectional view of an NROM cell between I and I as is shown in FIG. 1B. Generally, the NROM cell is an n-channel MOSFET device, wherein the gate dielectric is replaced with a storage layer stack 46. As is shown in FIG. 1A, the storage layer stack 46 is disposed above the channel 43 and under the gate electrode 44. The storage layer stack 46 comprises a silicon nitride layer 202 which stores the charge and two insulating silicon dioxide layers 201, 203 which sandwich the silicon nitride layer 202. The silicon dioxide layers 201, 203 have a thickness greater than 2 nm to avoid any direct tunneling. In the NROM cell shown in FIG. 1A, two charges are stored at each of the edges adjacent the n-doped source/drain regions 41, 42.

The NROM cell is programmed by channel hot electron injection (CHE), for example, whereas erasing is accomplished by hot hole enhanced tunneling (HHET), by applying appropriate voltages to the corresponding bit lines and word lines, respectively.

FIG. 1B shows a plan view of an exemplary memory device comprising an array 100 of a NROM cells. To be more specific, the memory cell array 100 comprises bit lines 4 extending in a first direction as well as word lines 2 extending in the second direction. Memory cells 45 are disposed between adjacent bit lines at each point of intersection of a substrate portion with a corresponding word line 2. The first and second source/drain regions 41, 42 form part of corresponding bit lines. The gate electrodes 44 form part of a corresponding word line. At a point of intersection of the word lines and bit lines, the bit lines and the word lines are insulated from each other by a thick silicon dioxide layer (not shown). In order to minimize the area required for the memory cell array 100, it is desirable to reduce the width of the word lines as much as possible. Nevertheless, for contacting the single word lines landing pads 111 having a minimum area are required. Usually, these landing pads 111 are disposed in a fan-out region 110 adjacent the memory cell array 100. In order to achieve a contact having an appropriate contact resistance, the area of each of the landing pads 111 must have a minimum value. In the peripheral portion 120, the transistors for controlling the action of the memory cell array are disposed. In particular, word line drivers, sense amplifiers and other transistors are disposed in the peripheral portion 120. Usually, the peripheral portion 120 is formed in the CMOS technology. Due to the special programming method for injecting a charge into the memory cells, the transistors disposed in the peripheral portion 120 have to withstand higher voltages than the transistors disposed in the array portion. As a consequence, the channel length of the corresponding transistors in the peripheral portion amount to approximately 0.25 μm and higher. In particular, this channel length cannot be reduced to achieve a reduced area of the peripheral portion 120 and, thus, the memory device.

As is shown in FIG. 1B, the word lines 2 have a minimum width wmin and a minimum distance dmin from each other. In order to increase the package density of such a memory cell array, it is desirable to reduce the width and the distance of the word lines. However, when shrinking the width of the word lines 2, a minimum contact area in the fan-out region 110 should be maintained. In addition, if the word line array is patterned by using a photolithography technique that is usually employed, the lateral dimensions of the word lines as well as the distance between neighboring word lines is limited by the minimal structural feature size which is obtainable by the technology used. A special problem arises if the landing pads and the array of conductive lines are to be patterned by one single lithographic step. In more detail, the area of the landing pads should be large, whereas the distance and the size of the conductive lines should be small. However, a lithographic step for simultaneously image different ground rules is very difficult to implement. Hence, a patterning method is sought by which it is possible to simultaneously pattern structures having a different ground rule.

### SUMMARY

According to the present invention, an improved memory device comprises: a semiconductor substrate having a surface; a plurality of first conductive lines extending in first direction; a plurality of second conductive lines extending in a second direction; a plurality of memory cells, each being accessible by addressing corresponding ones of the first and second conductive lines, the memory cells being at least partially formed in the semiconductor substrate; and a plurality of landing pads made of a conductive material, each of the landing pads being connected with a corresponding one of the second conductive lines. The plurality of second conductive lines comprises first and second subsets of conductive lines, the conductive lines of the first subset alternating with the conductive lines of the second subset. The landing pads connected with the second conductive lines of the first subset are disposed on a first side of each of the second conductive lines, and the landing pads connected with the second conductive lines of the second subset are disposed on a second side of each of the second conductive lines, the first side being opposite to the second side.

Accordingly, the conductive lines and the landing pads can be arranged such that two landing pads are arranged in a space between two neighboring conductive lines, whereas in a subsequent space between neighboring conductive lines no landing pad is arranged.

Moreover, the landing pads which are connected with two neighboring conductive lines can be arranged so as to be disposed on the opposite sides of the conductive lines.

For example, the first conductive lines can correspond to bit lines and the second conductive lines correspond to word lines of the memory device, the word lines being disposed above the bit lines.

Moreover, the landing pads can be arranged in a staggered fashion with respect to the second direction.

In addition, the landing pads can be arranged with an increasing distance with respect to a reference position of the memory device, the distance being measured along the second direction.

By way of example, two neighboring landing pads which are connected to two adjacent second conductive lines are disposed at the same height, the height being measured in the first direction with respect to a reference position.

For example, the landing pads can be disposed on one side of the plurality of second conductive lines.

Alternatively, the landing pads can be disposed on two opposite sides of the plurality of second conductive lines.

According to another aspect of the invention, an array of conductive lines is formed on or at least partially in a semiconductor substrate, the array comprising: a plurality of conductive lines extending in a first direction; and a plurality of landing pads made of a conductive material, each of the landing pads being connected to a corresponding one of the conductive lines. The plurality of conductive lines comprises first and second subsets of conductive lines, the conductive lines of the first subset alternating with the conductive lines of the second subset. The landing pads connected to the conductive lines of the first subset are disposed on a first side of each of the conductive lines, and the landing pads connected to the conductive lines of the second subset are disposed on a second side of each of the conductive lines, the first side being opposite to the second side.

The landing pads can be arranged in a staggered fashion with respect to the first direction. For example, the landing pads can be disposed on one side of the plurality of conductive lines. Alternatively, the landing pads can be disposed on two opposite sides of the plurality of conductive lines.

The width of each of the conductive lines can be less than 150 nm or even less than 100 nm, the width being measured perpendicularly with respect to the first direction. By way of example, the width of each of the landing pads can be less than 150 nm, the width being measured perpendicularly with respect to the first direction. Moreover, the length of each of the landing pads can be less than 150 nm, the length being measured with respect to the first direction.

According to a further aspect of the invention, a method of forming a memory device comprises: providing a semiconductor substrate having a surface; forming a plurality of first conductive lines on the surface of the semiconductor substrate, the first conductive lines extending in a first direction; forming a plurality of second conductive lines extending in a second direction, the second direction intersecting the first direction; and forming a plurality of memory cells, each memory cell being accessible by addressing corresponding ones of the first and second conductive lines. The plurality of first or second conductive lines are formed by: forming a layer stack comprising at least one conductive layer; forming a hard mask layer and patterning the hard mask layer to form hard mask lines having sidewalls; conformally depositing a sacrificial layer of a sacrificial material such that the deposited sacrificial layer has horizontal and vertical portions; removing the horizontal portions of the sacrificial layer so as to form lines of the sacrificial material adjacent the sidewalls of the hard mask lines; removing the hard mask lines to uncover portions of the layer stack; and etching the uncovered portions of the layer stack thereby forming single conductive lines.

After removing the hard mask lines two adjacent lines of the sacrificial material can be connected with each other. The method may further comprise etching the line of the sacrificial material at a predetermined position so as to isolate two adjacent lines of the sacrificial material.

The method can further comprise removing selected lines of the sacrificial material which is performed before etching the uncovered portions of the layer stack.

By removing selected lines of the sacrificial material, pairs of connected lines of the sacrificial material can be removed. The method further can further include etching the line of the sacrificial material at a predetermined position so as to isolate two adjacent lines of the sacrificial material. For example, the removal of selected lines of the sacrificial material and the etching of the line of the sacrificial material can be performed by a simultaneous etching operation.

The method may further comprise patterning the sacrificial layer to form pads of the sacrificial material, the pads being adjacent the lines of the sacrificial material. For example, patterning the sacrificial layer to form pads of the sacrificial material may include etching the sacrificial layer.

For example, the pads of the sacrificial material can be defined so that two pads of the sacrificial material are disposed between two adjacent hard mask lines.

By way of example, the hard mask layer may comprise silicon dioxide and the sacrificial material may comprise silicon.

According to a further aspect of the invention, a method of forming an array of conductive lines comprises: providing a semiconductor substrate having a surface; and providing a plurality of first conductive lines on the surface of the semiconductor substrate, the first conductive lines extending in a first direction. The plurality of first conductive lines are formed by: providing a layer stack comprising at least one conductive layer; providing a hard mask layer and patterning the hard mask layer to form hard mask lines having sidewalls; conformally depositing a sacrificial layer of a sacrificial material such that the deposited sacrificial layer has horizontal and vertical portions; removing the horizontal portions of the sacrificial layer so as to form lines of the sacrificial material adjacent the sidewalls of the hard mask lines; removing the hard mask lines so as to uncover portions of the layer stack; and etching the uncovered portions of the layer stack thereby forming single conductive lines.

In addition, the method may comprise patterning the sacrificial layer to form pads of the sacrificial material, the pads being adjacent the lines of the sacrificial material.

For example, the pads of the sacrificial material may be defined in a final region of the array of conductive lines.

By way of example, all the pads of the sacrificial material can be defined in a final region which is disposed on one side of the array of conductive lines.

Alternatively, all the pads of the sacrificial material are defined in final regions which are disposed on opposite sides of the array of conductive lines.

The above and still further features and advantages of the present invention will become apparent upon consideration of the following detailed description of specific embodiments thereof, wherein like numerals define like components in the drawings.

### BRIEF DESCRIPTION OF THE DRAWINGS

FIG. 1A shows a cross-sectional view of an NROM cell.

FIG. 1B shows a plan view of a memory device comprising NROM cells.

FIG. 2 shows a cross-sectional view of a substrate after patterning a photoresist layer.

FIG. 3 shows a cross-sectional view of the substrate after patterning a hard mask layer.

FIG. 4 shows a cross-sectional view of the substrate after thinning the hard mask lines.

FIG. 5 shows a cross-sectional view of the substrate after depositing a sacrificial layer.

FIG. 6A shows a cross-sectional view of the substrate after patterning a photoresist layer.

FIG. 6B shows a plan view of the substrate after patterning the photoresist layer.

FIG. 7A shows a cross-sectional view of the substrate after performing an etching step.

FIG. 7B shows a plan view of the substrate after performing the etching step.

FIG. 8A shows a cross-sectional view of the substrate after removing the hard mask material.

FIG. 8B shows a plan view of the substrate after removing the hard mask material.

FIG. 9A shows a cross-sectional view of the substrate after patterning a photoresist layer.

FIG. 9B shows a plan view of the substrate after patterning the photoresist layer.

FIG. 10A shows a cross-sectional view of the substrate after performing an etching step.

FIG. 10B shows a plan view of the substrate after performing the etching step.

FIG. 11 shows a cross-sectional view of the substrate after performing a further etching step.

FIG. 12A shows a cross-sectional view of the memory device according to the present invention.

FIG. 12B shows a plan view of a memory device according to the present invention.

FIG. 13 shows a plan view of a memory device according to another embodiment of the present invention.

FIG. 14 shows a plan view of an array of conductive lines according to an embodiment of the present invention.

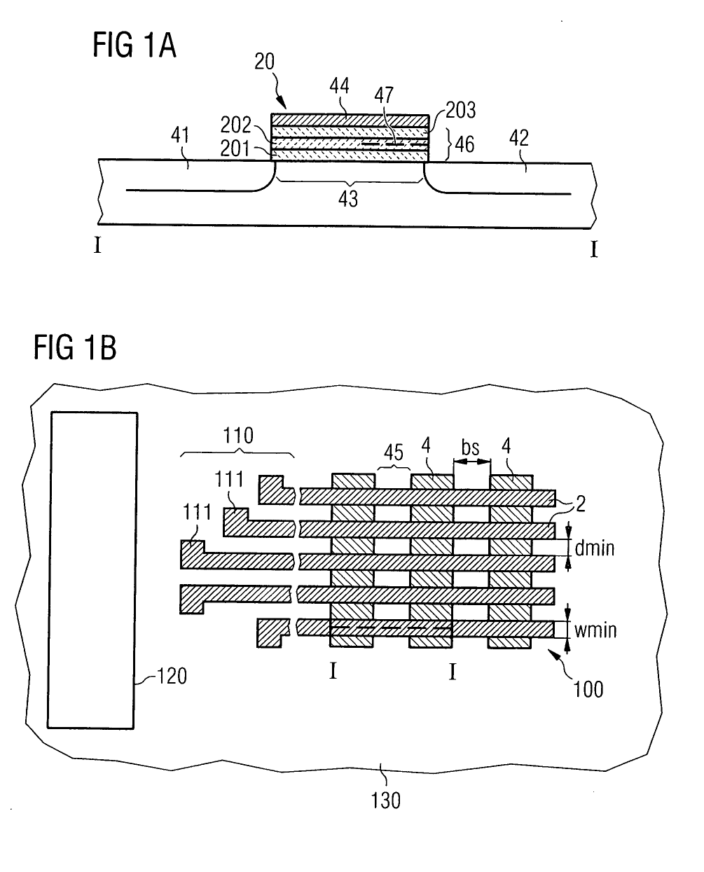

### DETAILED DESCRIPTION

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated, as they become better understood by reference to the following detailed description. The elements of the drawings are not necessarily to scale relative to each other. Like reference numerals designate corresponding similar parts.

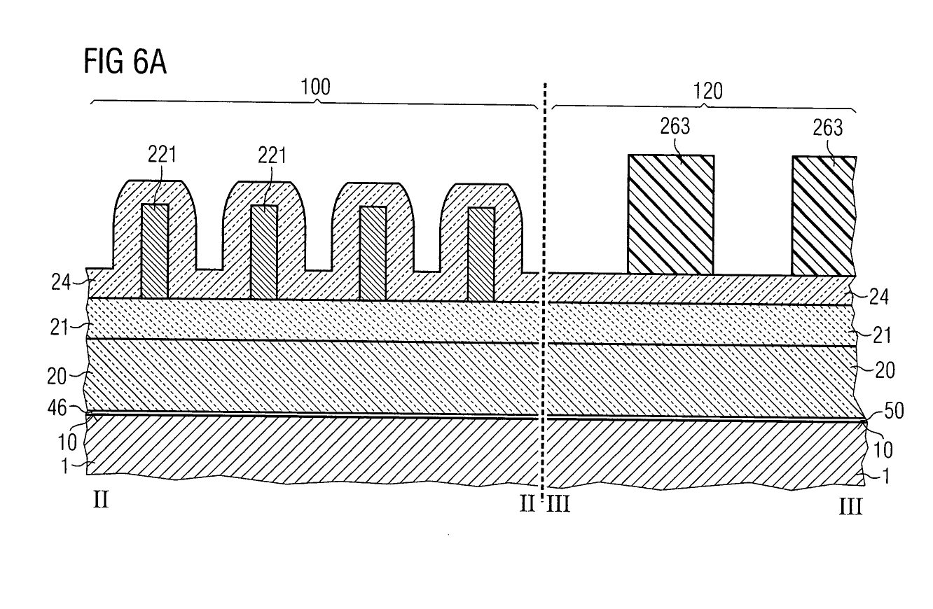

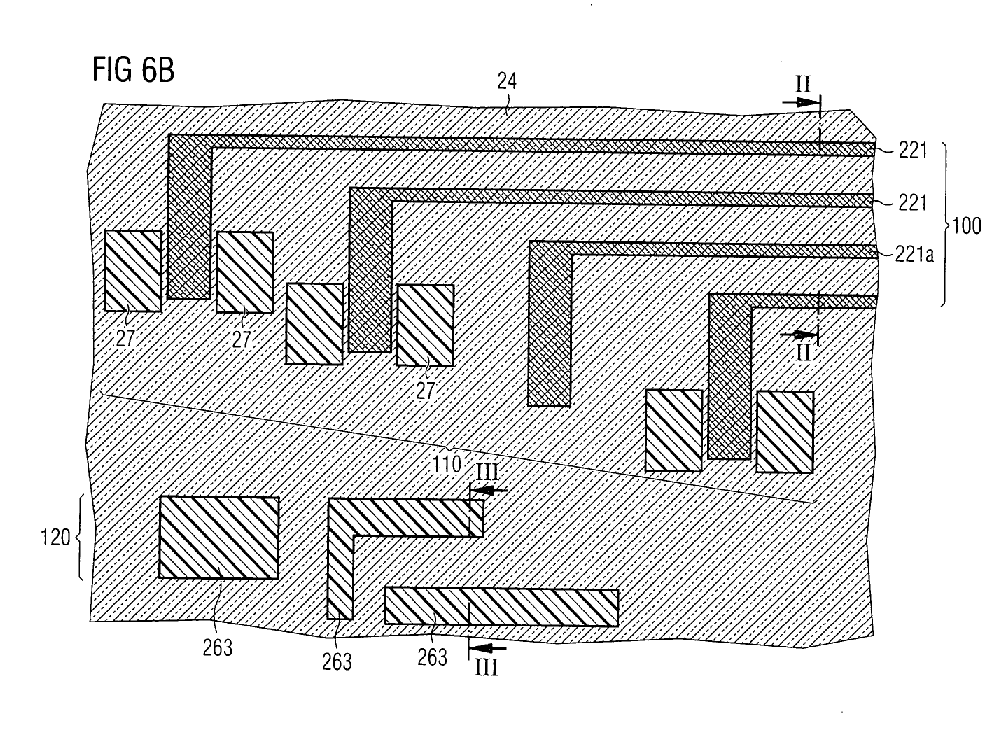

In the following cross-sectional views, the left-hand portion shows the cross-sectional view of the array portion 100, whereas the right-hand portion shows the cross-sectional view of the peripheral portion 120. In particular, the left-hand portion is taken between II and II, whereas the right-hand portion is taken between III and III as is, for example, illustrated in FIG. 6B.

Starting point for performing the method of the present invention is a semiconductor substrate, in particular, a silicon substrate, which is, for example, p-doped. In the substrate portion in which the peripheral portion of the memory device is to be formed, a gate oxide layer 50 is grown by thermal oxidation. In the array portion, after depositing a storage layer stack comprising a first SiO₂ layer having a thickness of 1.5 to 10 nm, a Si₃N₄ layer having a thickness of 2 to 15 nm followed by a second SiO₂ layer having a thickness of 5 to 15 nm, the storage layer stack is patterned so as to form lines. After covering the lines with a protective layer and forming spacers adjacent the sidewalls of the lines of the layer stack, an implantation step is performed so as to define the source/drain regions in the exposed portions.

A bit line oxide is provided by performing a deposition step, followed by a step of depositing a word line layer stack. These steps are well known to the person skilled in the art of NROM devices, and a detailed description thereof is omitted.

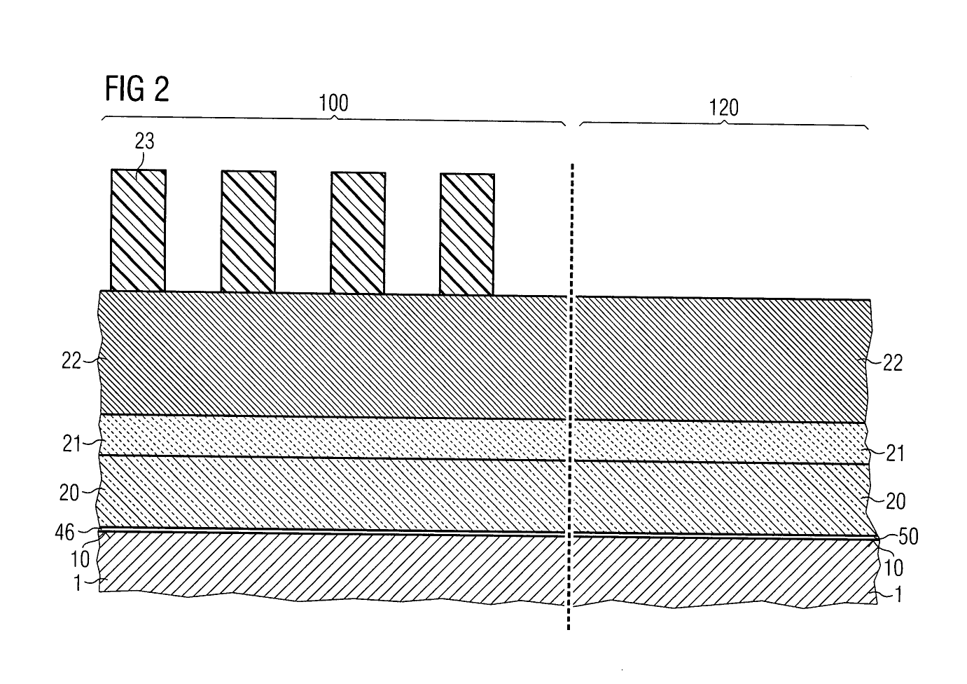

As is shown in FIG. 2, as a result, on the surface 10 of the semiconductor substrate 1, in particular, a p-doped semiconductor substrate, in the array portion 100, the storage layer stack 46, a word line layer stack 20, a silicon nitride cap layer 21 and a hard mask layer 22 are disposed. The word line layer stack 20 usually comprises segments of a first polysilicon layer and a second polysilicon layer having a total thickness of approximately 70 to 110 nm, followed by a titanium layer (not shown), a tungsten nitride layer having a thickness of approximately 5 to 20 nm and a tungsten layer having a thickness of approximately 50 to 70 nm. On top of the tungsten layer, the silicon nitride layer 21 having a thickness of approximately 120 to 180 nm is disposed. On top of the silicon nitride layer 21, the hard mask layer 22 is disposed. In the present embodiment, the hard mask layer 22 is made of silicon dioxide, which can, for example, be formed by a deposition method using TEOS (tetraethylorthosilicate) as a starting material. The hard mask layer 22 can have a thickness of approximately 40 to 100 nm.

In the peripheral portion 120 the same layer stack is disposed on the silicon substrate 1, with the peripheral gate oxide layer 50 being disposed instead of the storage layer stack 46. In particular, the thickness of the peripheral gate oxide layer 50 can be different from the thickness of the storage layer stack 46 in the array portion.

A photoresist layer 23 is deposited on the resulting surface in the array portion 100 as well as in the peripheral portion 120 and patterned so as to form single lines which are disposed in a periodic manner. The resulting structure is shown in FIG. 2, wherein a patterned photoresist layer 23 is shown. In particular, the photoresist layer 23 is patterned in a lines/spaces pattern. The pitch of the lines/spaces pattern, i.e., the sum of the line width and the space width, should be approximately twice the line width to be achieved.

As is commonly used, an antireflective coating (ARC) layer may be disposed on top of the hard mask layer. Instead of the silicon dioxide layer, any other suitable material can be used as the material of the hard mask layer. For example, the hard mask layer can also be made of carbon. In particular, if carbon is taken as the hard mask material, it is necessary to deposit an SiON layer on top of the carbon layer in order to enable the resist strip. In addition, the ARC layer can be disposed beneath the photoresist layer.

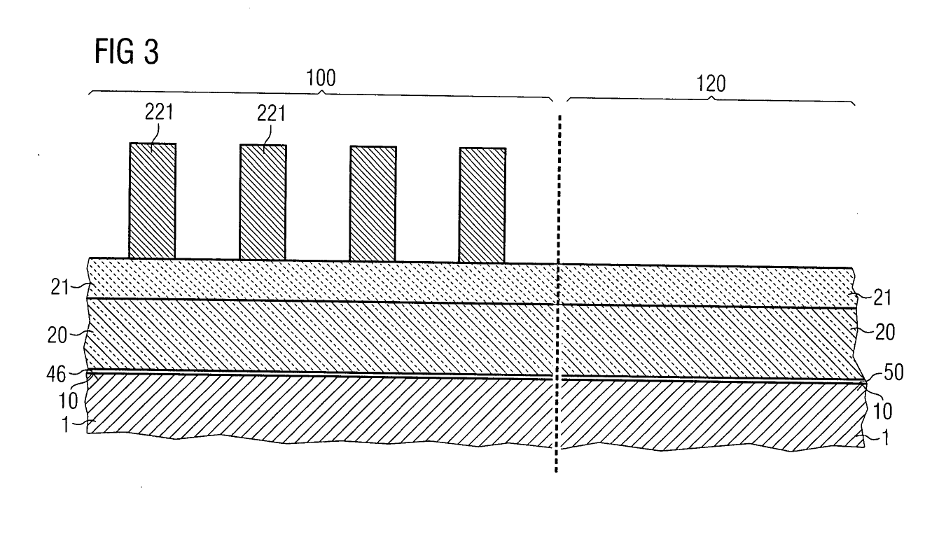

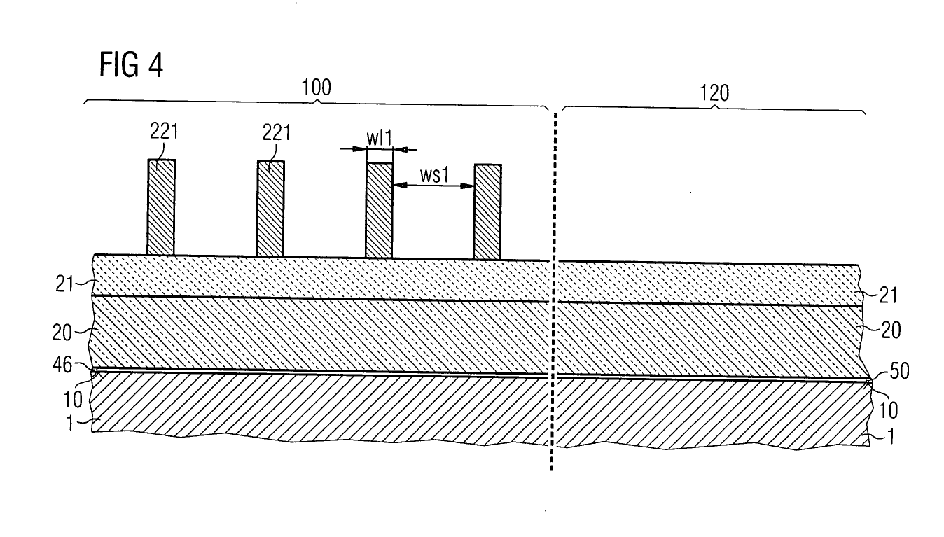

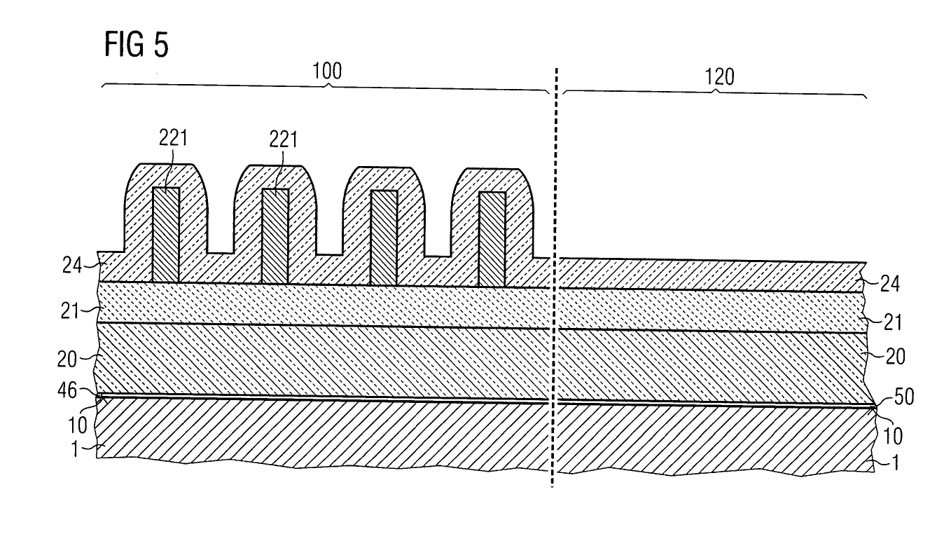

In the next step, the photoresist pattern is transferred to the hard mask layer 22. In particular, an etching step is performed, taking the photoresist mask as an etching mask. After removing the photoresist material 23, the structure shown in FIG. 3 is obtained, wherein single lines 221 of the hard mask material 22 are formed. Stated differently, for obtaining the structure shown in FIG. 3, starting from the structure shown in FIG. 2, the SiO₂ layer 22 is etched at the uncovered portions and, thereafter, a resist stripping step is performed. For further reducing the line width of the silicon dioxide lines 221, an oxide recess step can be performed so as to reduce the line width of the silicon dioxide lines 221. Alternatively, the photoresist material can be exposed by an over-exposing step in the step which has been described with reference to FIG. 2, so as to obtain a line width wl1 of each of the lines which is smaller than the width ws1 of the spaces between adjacent lines. A cross-sectional view of the resulting structure is shown in FIG. 4.

Referring to FIG. 5, in the next step, a sacrificial layer 24 is deposited on the resulting surface. In particular, the sacrificial layer 24 can be made of polysilicon. The material of the sacrificial layer can be arbitrarily chosen, with the proviso that the sacrificial layer should be able to be etched selectively with respect to the cap layer of the word line layer stack, the cap layer usually being made of silicon nitride. In addition, the sacrificial layer 24 must be able to be etched selectively with respect to the hard mask material 22. The thickness of the sacrificial layer should be approximately equal to the target width (CD “critical dimension”) of the resulting word lines, incremented by approximately 10 nm. For example, if a target CD of the word line of 50 nm is to be achieved, the thickness of the sacrificial layer should be about 60 nm. Alternatively, if the target width of the word lines is to be about 25 nm, the thickness of the sacrificial layer should be approximately 35 nm. Nevertheless, the optimum thickness of the sacrificial layer depends on the minimal structural feature size F of the technology employed. As can be seen from FIG. 5, the sacrificial layer 24 is conformally deposited so as to cover the lines 221 in the array portion, while forming a planar layer in the peripheral portion 120. The materials of the sacrificial layer as well as of the hard mask layer can be arbitrarily selected. However, it is necessary to select a hard mask material which can be etched selectively with respect to the material of the sacrificial layer and the material of the word line cap layer 21.

Referring next to FIGS. 6A and 6B, a photoresist layer 26 is then deposited and patterned. Consequently, the array portion 100 is uncovered, whereas in the peripheral portion peripheral photoresist pads 263 are formed. A cross-sectional view of the resulting structure is shown in FIG. 6A, whereas a plan view on the resulting structure is shown in FIG. 6B. As can be further seen, in addition, photoresist pads 27 are formed adjacent the vertical portions of the sacrificial layer 24 in the fan-out region 110. Landing pads are to be formed at those portions which are covered by the photoresist pads 27.

As can be seen from FIG. 6B, the structure comprises an array portion 100, in which the word lines are to be formed. In particular, lines 221 of the hard mask material as well as the vertical portions of the sacrificial layer 24 are formed. In the fan-out region 110, photoresist pads 27 are defined. Moreover, a peripheral portion 120 is defined at the peripheries of the resulting memory device.

As can further be gathered from FIG. 6B, the photoresist pads 27 are patterned in a manner so that no photoresist pads 27 are defined adjacent one selected line 221a of the hard mask material. This is the region of the memory array, in which the word lines are to be removed in a later process step. Moreover, the photoresist pads 27 are disposed in the spaces between neighboring hard mask lines 221.

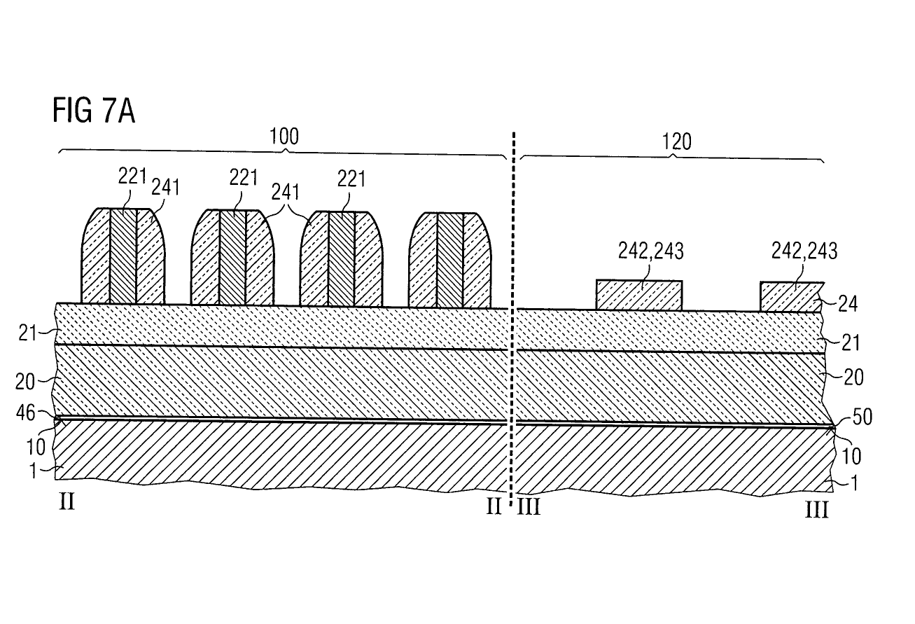

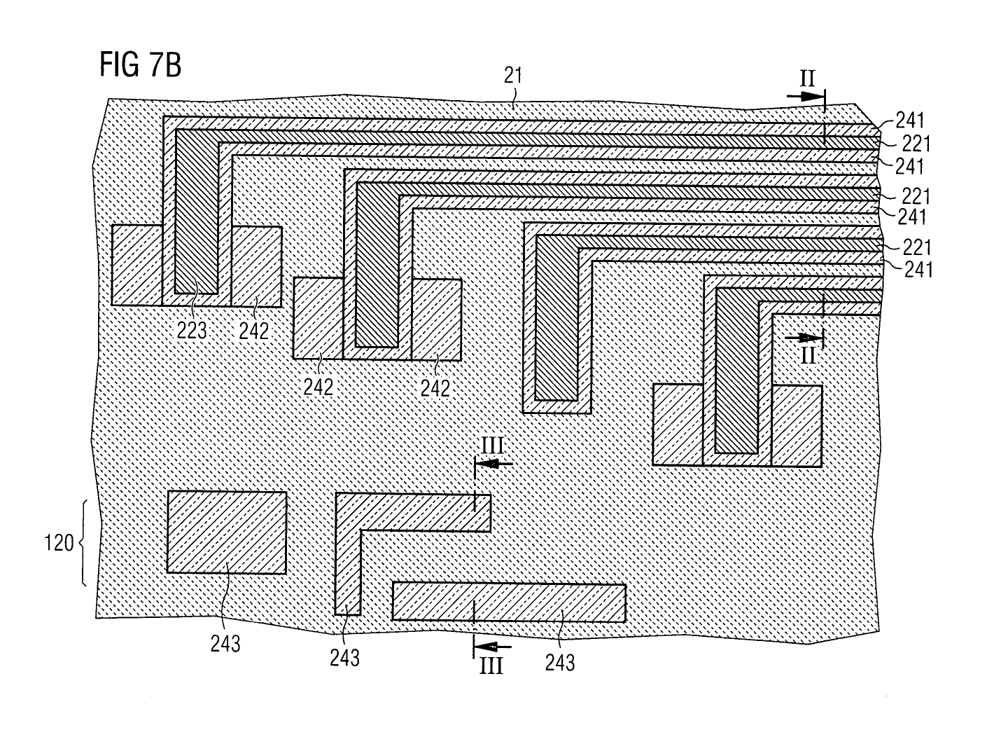

Referring to FIGS. 7A and 7B, the horizontal portions of the sacrificial layer 24 next are etched. Consequently, spacers 241 of the sacrificial layer are formed in the array portion adjacent the vertical sidewalls 220 of the hard mask lines 221. In other words, the spacers 241 of polysilicon are formed adjacent the hard mask lines 221. In addition, in the peripheral portion as well as in the fan-out region the polysilicon layer is not removed from the portions, which are covered by the photoresist material 26.

FIG. 7A shows the resulting structure after removing the photoresist material. As can be seen from the left hand portion, which shows the array portion, spacers 241 are formed adjacent the sidewalls 220 of the hard mask lines 221. In addition, in the peripheral portion, polysilicon pads 242 as well as peripheral polysilicon pads 243 are formed.

FIG. 7B shows a plan view on the resulting structure. As can be seen, lines of the sacrificial layer 241 are formed so that two adjacent lines 241 are connected at a final region 223 of the lines 221 of the hard mask material. At the final region 223 of the lines 221 of the hard mask material, polysilicon pads 242 are formed. In the spaces between adjacent hard mask lines, two polysilicon pads 242 are disposed. Each of the two polysilicon pads 242 is assigned to different polysilicon spacers 241. Landing pads for contacting the resulting word lines are to be formed at the position of these polysilicon pads 242. In addition, peripheral polysilicon pads 243 are formed. The polysilicon material 242, 243 and 241 is isolated by means of the cap layer of the word line layer stack 21, which can in particular be made of silicon nitride.

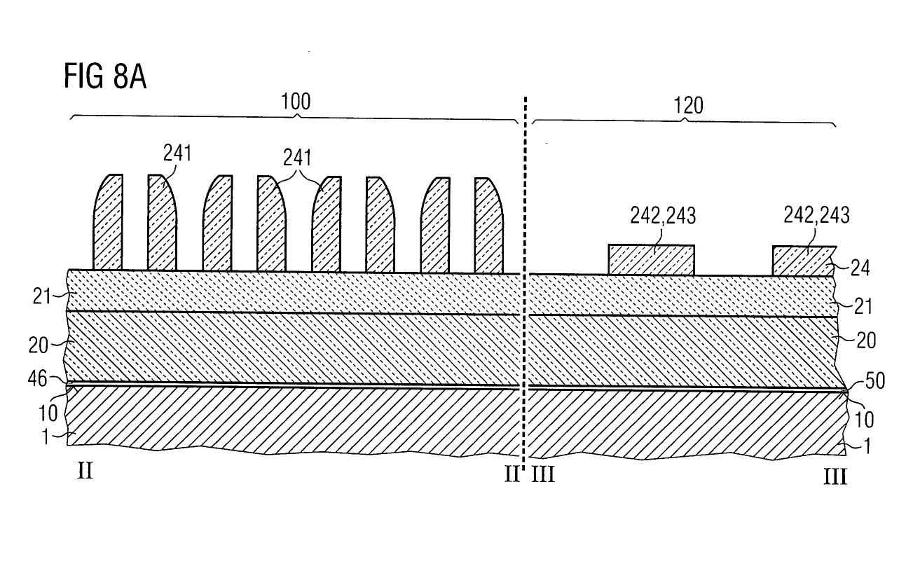

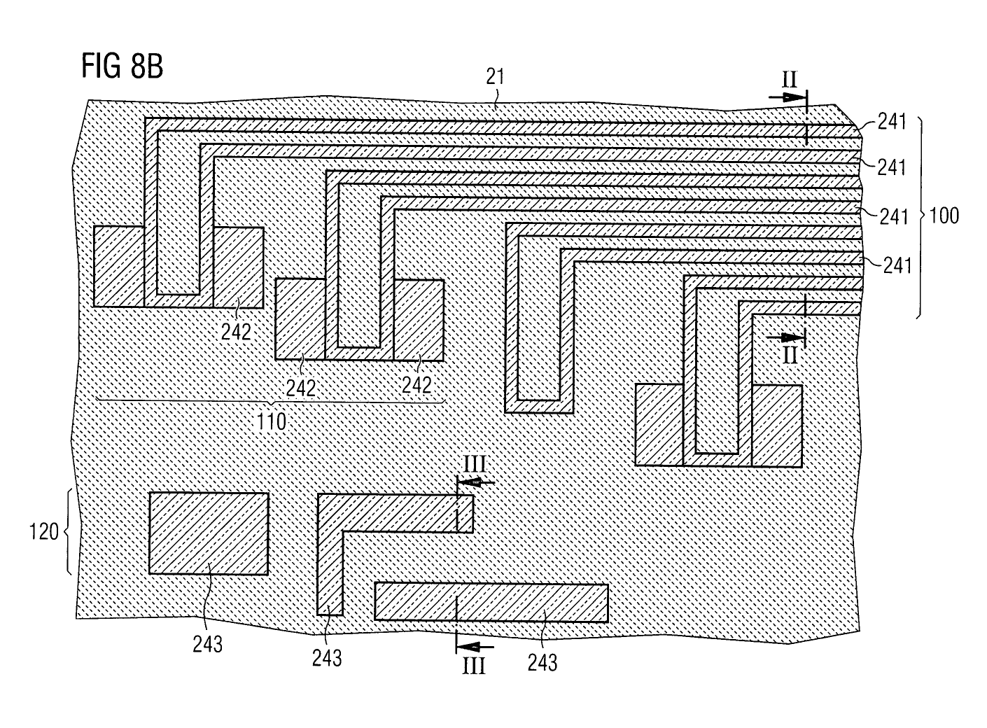

Referring now to FIGS. 8A and 8B, the hard mask material 22 is then removed, for example by wet etching. Optionally, the spaces between neighboring spacers 241 of the sacrificial material can be filled with the hard mask material, followed by a planarizing step, before performing the step of removing the hard mask material. In this case, an attack of the etchant on the silicon nitride cap layer 21 is advantageously avoided.

After removing the hard mask material 22, as a result, isolated spacers 241 which are made of the sacrificial material remain on the surface of the cap nitride layer 21 in the array portion 100. The peripheral portion remains unchanged. The resulting structure is shown in FIG. 8A. A plan view on the resulting structure is shown in FIG. 8B. As can be seen, single lines 241 which are made of polysilicon are formed in the array portion. Moreover, in the fan-out region 110 polysilicon pads 242 are formed, and in the peripheral portion peripheral polysilicon pads 243 are formed. As can further be seen, adjacent pairs of the sacrificial spacers 241 are connected with each other. The cap nitride material 21 is disposed between the single polysilicon portions. In order to separate adjacent lines 241 of the sacrificial material, another photolithographic step is performed so as to isolate the lines 241 from each other and, in addition, to remove selected spacers, so that, as a result, selected word lines will be removed in a later process step.

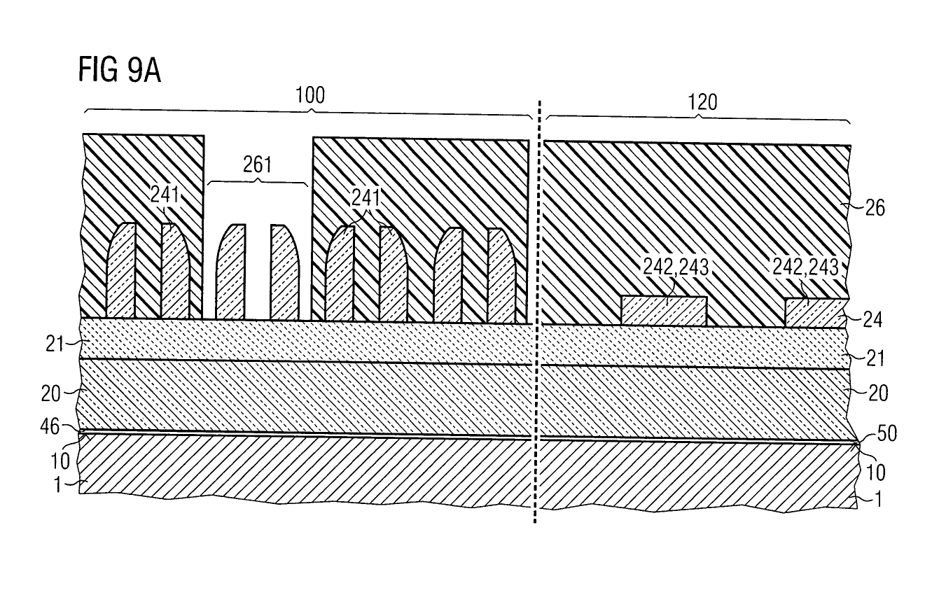

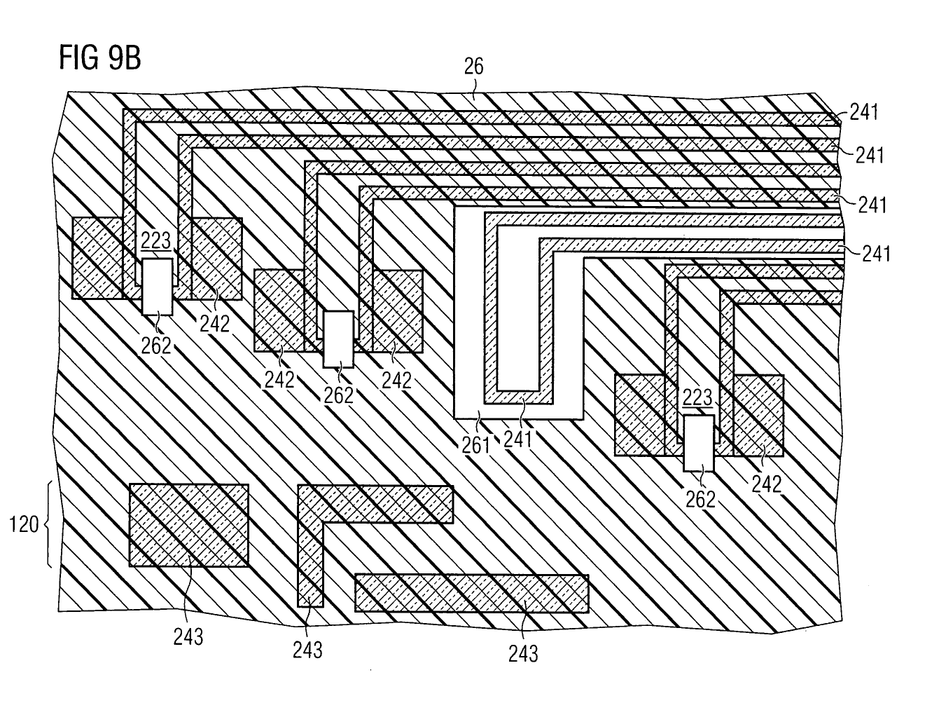

To this end, as shown in FIGS. 9A and 9B, the entire surface of the memory device is covered with a further photoresist layer 26 and is patterned in the array portion as well as in the fan-out region 110. In particular, array openings 261 are formed at those position, at which spaces between selected word lines are to be formed. Moreover, fan-out openings 262 are formed at the final regions 223. FIG. 9A shows a cross-sectional view of the resulting structure. As can be seen, array openings 261 are formed at predetermined positions. Moreover, FIG. 9B shows a plan view on the resulting structure. As can be seen, an array opening 261 is formed at a position corresponding to a pair of spacers 241. Moreover, a fan-out opening 262 is formed between adjacent polysilicon pads 242.

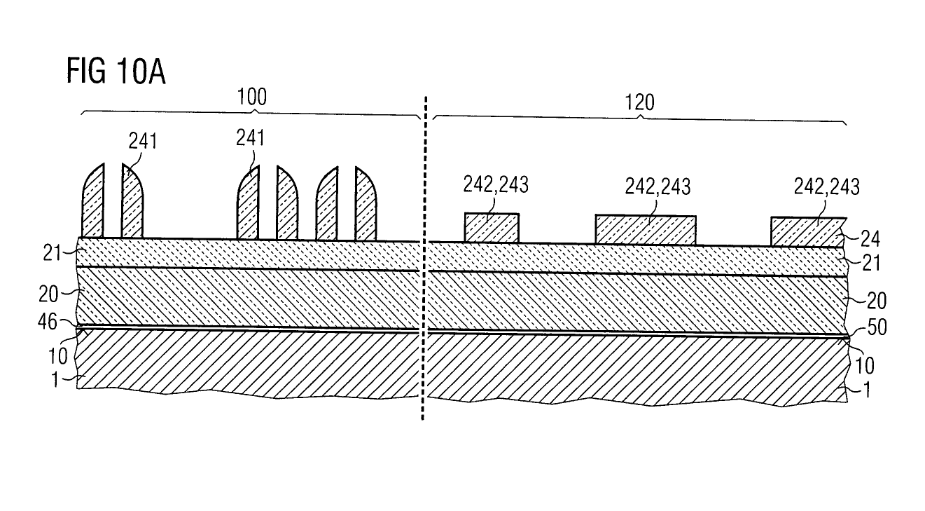

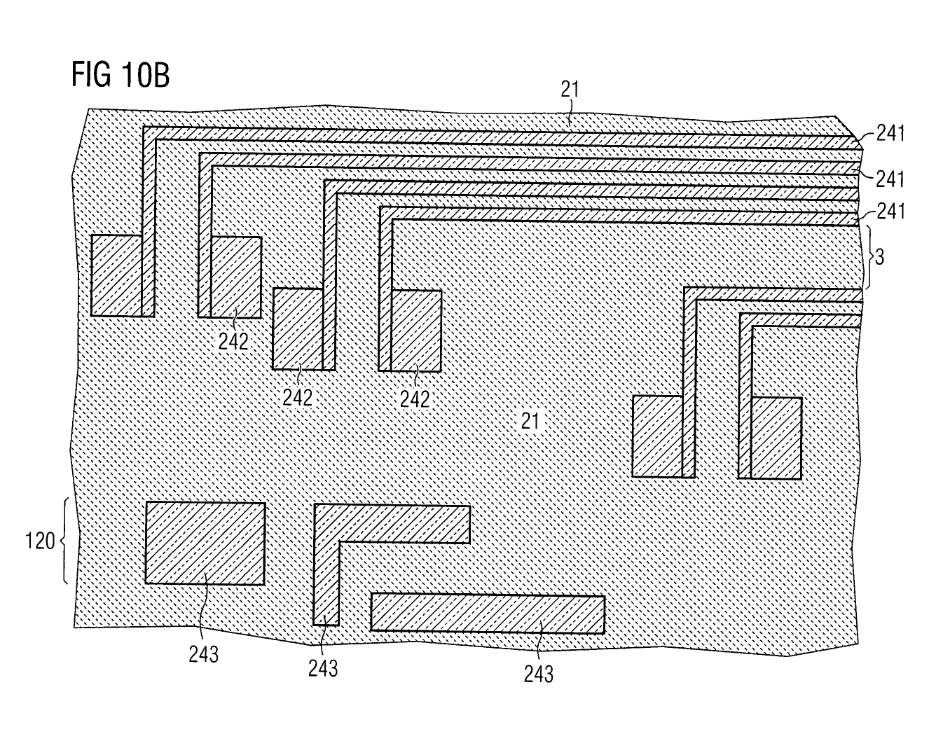

In the next step, an etching step for etching polysilicon is performed so as to remove the uncovered portions of the polysilicon spacer 241. FIG. 10A shows a cross-sectional view of the resulting structure after removing the photoresist material 26. As can be seen, polysilicon pads 242 and peripheral polysilicon pads 243 are formed in the peripheral portion 120, whereas in the array portion 100 selected spacers 241 are removed.

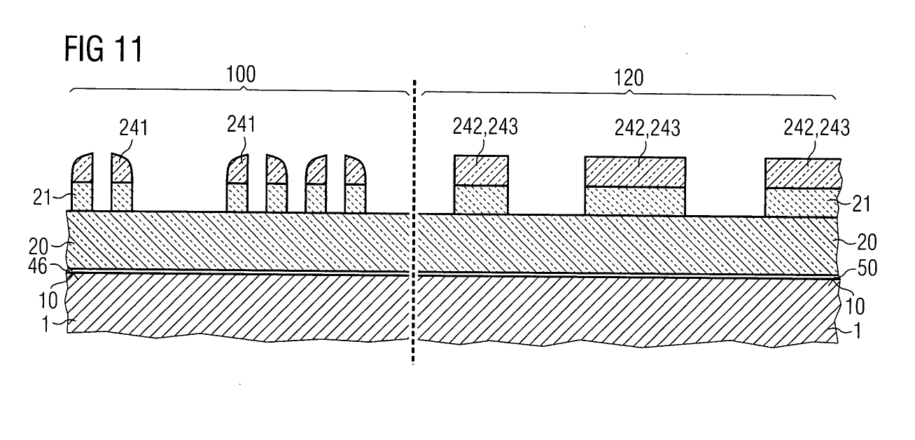

FIG. 10B shows a plan view on the resulting structure. As can be seen, the spacers 241 have been removed from the word line removal region 3. In addition, adjacent spacers 241 are now isolated from each other. In the next step, an etching step for etching the cap nitride layer 21 is performed, resulting in the structure shown in FIG. 11. More specifically, the silicon nitride material is etched selectively with respect to polysilicon. Accordingly, the polysilicon spacers 241 as well as the polysilicon pads 242, 243 are taken as an etching mask when etching the silicon nitride cap layer 21 for defining the word lines, the landing pads and the peripheral gate electrodes.

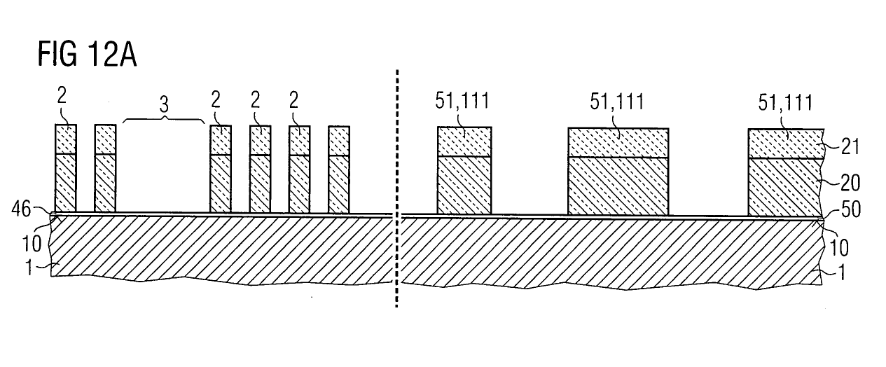

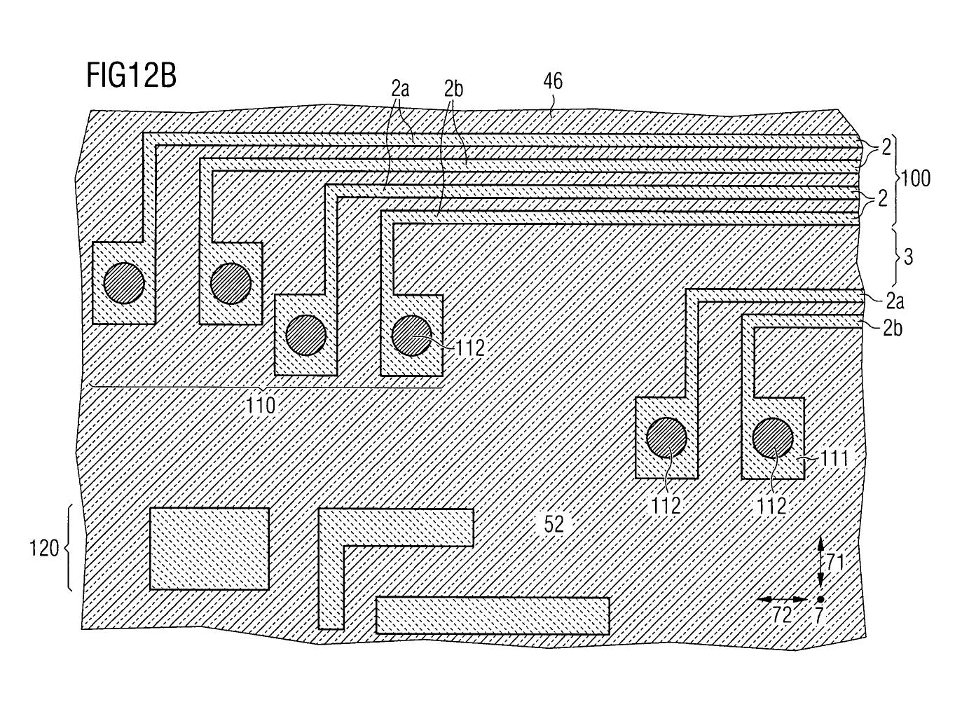

As can be seen from FIG. 11, in the array portion 100 as well as in the peripheral portion 120, layer stacks of the cap nitride layer 21, and the sacrificial layer 24 are patterned. Thereafter, an etching step for etching the word line layer stack is performed so that as a result single word lines 2 are formed in the array portion. FIG. 12A shows a cross-sectional view of the resulting structure. As can be seen, in the array portion 100, single word lines 2 are formed, with word line removal regions 3 being disposed at predetermined positions. In other words, the word line removal region 3 corresponds to an enlarged space between adjacent word lines 2. Moreover, in the peripheral portion, peripheral gate electrodes 51 are formed.

The step of etching the word line layer stack can be a single etching step of etching the entire layer stack. Optionally, the step of etching the word line layer stack may comprise several sub-steps in which only single layers or a predetermined number of layers are etched. In addition, after a sub-step of etching a predetermined number of layers, a liner layer may be deposited so as to protect an underlying layer of the layer stack against the etching.

FIG. 12B shows a plan view on the resulting structure. As can be seen, in the array portion 100, the single word lines 2 are protected by the cap nitride layer 21. In the fan-out region 110 landing pads 111 are formed, on which contact pads are positioned. Moreover, in the peripheral portion 120, the peripheral circuitry as is commonly used is formed. As will be apparent to the person skilled in the art, different arrangements of the landing pads 111 can be used so as to obtain an improved packaging density of the landing pads in the fan-out region 110.

As can further be seen from FIG. 12B the single word lines 2 are connected with the landing pads 111. The fan-out region 110 is isolated from the peripheral portion 120 by the silicon dioxide material 52. The contact pads 112 can be connected with a corresponding metal wiring in the following process step. Starting from the views shown in FIGS. 12A and 12B, the memory device will be completed in a manner as is known to the person skilled in the art. In particular, the peripheral portion of the memory device is completed. In addition, in the array portion, insulating layers comprising BPSG and SiO₂ layers are deposited, followed by the definition of bit line contacts in the word line removal region 3. In the MO wiring layer, conductive lines supporting the bit lines are provided, so that finally a completed memory device is obtained.

In the arrangement shown in FIG. 12B, the plurality of word lines comprises a first and a second subsets of word lines. In particular, the word lines 2a of the first subset alternate with the word lines 2b of the second subset. As can be recognized, the landing pads which are connected with the word lines 2a of the first subset are disposed on the left hand side of the word lines, whereas the landing pads 111 which are connected with the word lines 2b of the second subset are disposed on the right hand side of the word lines. For example, the width of the word lines 2 can be less than 150 nm, optionally less than 100 nm or less than 60 nm, the width being measured along the first direction 71. The width of the word lines 2 can be equal to the width of the spaces isolating neighboring word lines. The width of the word lines 2 may as well be different from the width of the spaces.

The width of the landing pads may be less than 150 nm, the width being measured along the first direction 71. In addition, the length of the landing pads may be less than 150 nm, optionally less than 100 nm, the length being measured along the second direction 72.

As can be seen from FIG. 12B, the landing pads 111 are arranged in a staggered fashion with respect to the second direction. In particular, the landing pads are arranged with an increasing distance with reference to a reference position 7 of the memory device. In particular, the distance is measured along the second direction 72.

As can further be seen from FIG. 12B, two neighboring landing pads which are connected with two adjacent second conductive lines are disposed at the same height. In particular, the height is measured along the first direction with respect to the reference position 7 of the memory device. In the arrangement shown in FIG. 12B, the landing pads 111 are arranged on one side of the plurality of conductive lines.

Although the above description relates to a process flow for forming a memory device comprising a plurality of conductive lines, it is clearly to be understood that the present invention can be implemented in various manners. In particular, the array of conductive lines can be implemented with any kind of devices and, in addition, with any kind of memory devices which are different from the specific memory device explained above.

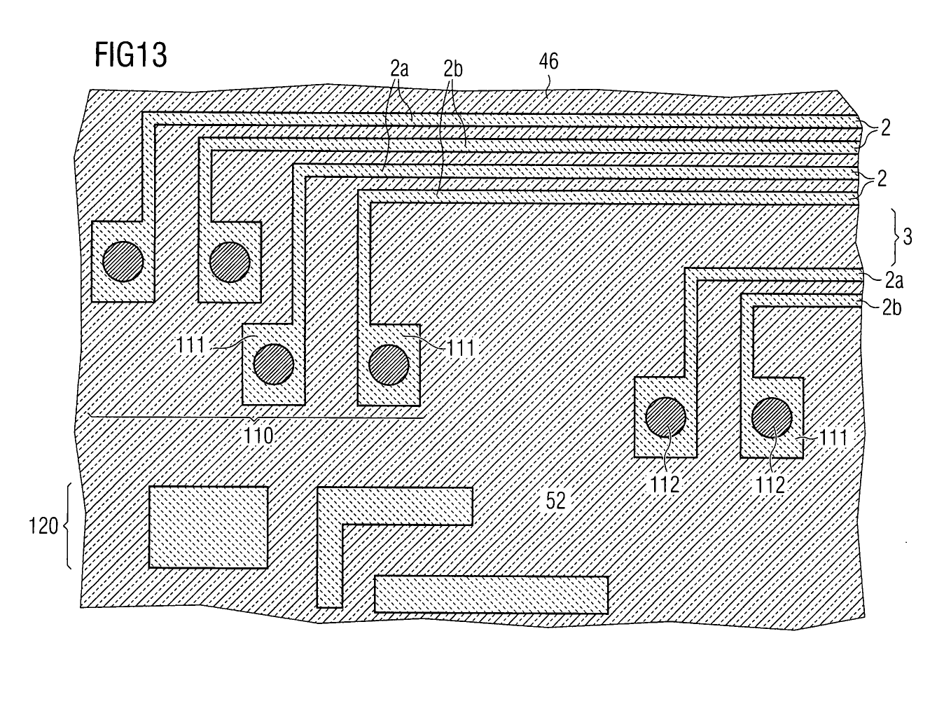

FIG. 13 shows a further embodiment of the memory device or the array of conductive lines of the present invention wherein the arrangement of the landing pads 111 is changed. According to this embodiment, a larger packaging density of the landing pads is achieved.

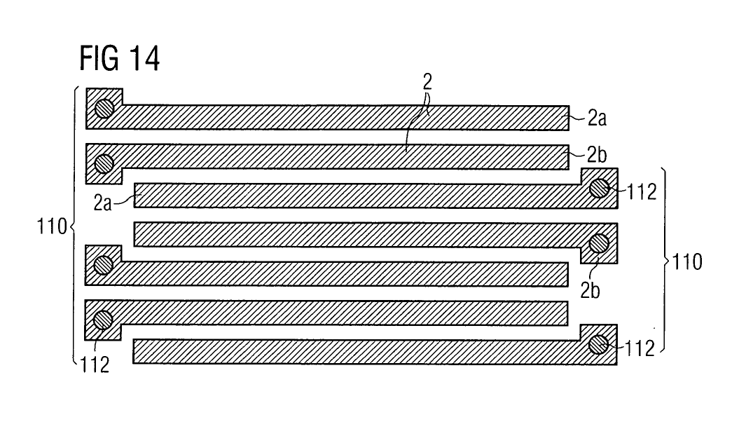

FIG. 14 shows an embodiment of the array of conductive lines or the memory device of the present invention. In particular, the landing pads 111 are disposed on either sides of the array of conductive lines.

Having described preferred embodiments of the invention, it is believed that other modifications, variations and changes will be suggested to those skilled in the art in view of the teachings set forth herein. It is therefore to be understood that all such variations, modifications and changes are believed to fall within the scope of the present invention as defined by the appended claims. Although specific terms are employed herein, they are used in a generic and descriptive sense only and not for purposes of limitation.

### LIST OF REFERENCES

1 semiconductor substrate
10 substrate surface
2 word line
2a word line of the first subset
2b word line of the second subset
20 word line layer stack
201 silicon dioxide
202 silicon nitride
203 silicon dioxide
21 Si₃N₄ layer
22 silicon dioxide layer
220 sidewall of silicon dioxide line
221 silicon dioxide line
221a selected line
223 final region
23 photoresist layer
24 polysilicon layer
241 polysilicon spacer
242 polysilicon pad
243 peripheral polysilicon pad
26 photoresist
261 array opening
262 fan-out opening
263 peripheral photoresist
27 photoresist pad
29 SiO₂ layer
3 word line removal region
4 bit line
41 first source/drain region
42 second source/drain region
43 channel
44 gate electrode
45 memory cell
46 storage layer stack
47 stored charge
50 peripheral gate oxide
51 peripheral gate electrode
52 peripheral SiO₂ layer
60 point of reference
61 straight line
62 boundary line
7 reference position
71 first direction
72 second direction
100 memory cell array
110 fan-out region
111 landing pad
112 contact
113 space
114 hard mask pad
114a first set of hard mask pads
114b second set of hard mask pads
120 peripheral portion
121 patterned peripheral portion
130 memory device

What is claimed is:

1. A memory device, comprising:
a semiconductor substrate having a surface;
a plurality of first conductive lines extending in a first direction;
a plurality of second conductive lines extending in a second direction, the plurality of second conductive lines comprising first and second subsets of conductive lines, the conductive lines of the first subset alternating with the conductive lines of the second subset;
a plurality of memory cells at least partially formed in the semiconductor substrate, individual ones of the memory cells being accessible by addressing corresponding ones of said first and second conductive lines; and
a plurality of landing pads comprising a conductive material, individual ones of the landing pads being connected to corresponding ones of said second conductive lines, wherein the landing pads connected to the first subset of the second conductive lines are disposed on a first side of the second conductive lines, and the landing pads connected to the second subset of the second conductive lines are disposed on a second side of the second conductive lines, the first side being opposite to the second side.

2. The memory device of claim 1, wherein the first conductive lines correspond to bit lines and the second conductive lines correspond to word lines of the memory device, the word lines being disposed above the bit lines relative to the semiconductor substrate.

3. The memory device of claim 1, wherein the landing pads are arranged in a staggered fashion with respect to the second direction.

4. The memory device of claim 3, wherein the landing pads are arranged with an increasing distance with respect to a reference position of the memory device, the distance being measured along the second direction.

5. The memory device of claim 1, wherein two neighboring landing pads which are connected with two adjacent second conductive lines are disposed at a same height, the height being measured in the first direction with respect to a reference position.

6. The memory device of claim 1, wherein the landing pads are disposed on one side of the plurality of second conductive lines.

7. The memory device according to claim 1, wherein the landing pads are disposed on two opposite sides of the plurality of second conductive lines.

8. An array of conductive lines, the array being formed on or at least partially in a semiconductor substrate, the array comprising:
a plurality of conductive lines extending in a first direction, wherein the plurality of conductive lines comprises first and second subsets of conductive lines, the conductive lines of the first subset alternating with the conductive lines of the second subset; and
a plurality of landing pads comprising a conductive material, individual ones of the landing pads being connected to corresponding ones of said conductive lines, wherein the landing pads connected to the first subset of conductive lines are disposed on a first side of the conductive lines, and the landing pads connected to the second subset of conductive lines are disposed on a second side of the conductive lines, the first side being opposite to the second side.

9. The array of conductive lines of claim 8, wherein the landing pads are arranged in a staggered fashion with respect to the first direction.

10. The array of conductive lines of claim 8, wherein the landing pads are disposed on one side of the plurality of conductive lines.

11. The array of conductive lines of claim 8, wherein the landing pads are disposed on two opposite sides of the plurality of conductive lines.

12. The array of conductive lines of claim 8, wherein the width of each of the conductive lines is less than 150 nm, the width being measured perpendicularly with respect to the first direction.

13. The array of conductive lines of claim 12, wherein the width of each of the conductive lines is less than 100 nm.

14. The array of conductive lines of claim 8, wherein the width of each of the landing pads is less than 150 nm, the width being measured perpendicularly with respect to the first direction.

15. The array of conductive lines of claim 8, wherein the length of each of the landing pads is less than 150 nm, the length being measured with respect to the first direction.

16. A method of forming a memory device comprising:
providing a semiconductor substrate having a surface;
forming a plurality of first conductive lines on the surface of the semiconductor substrate, the first conductive lines extending in a first direction;
forming a plurality of second conductive lines extending in a second direction that intersects the first direction; and
forming a plurality of memory cells, individual ones of the memory cells being accessible by addressing corresponding ones of said first and second conductive lines,
wherein forming the plurality of first conductive lines or the plurality of second conductive lines includes:
forming a layer stack comprising at least one conductive layer;
forming a hard mask layer and patterning the hard mask layer to form hard mask lines having sidewalls;
conformally depositing a sacrificial layer of a sacrificial material such that the deposited sacrificial layer has horizontal and vertical portions;
removing the horizontal portions of the sacrificial layer to form lines of the sacrificial material adjacent the sidewalls of the hard mask lines;
removing the hard mask lines to uncover portions of the layer stack; and
etching the uncovered portions of the layer stack thereby forming single conductive lines.

17. The method of claim 16, wherein, after removing the hard mask lines, two adjacent lines of the sacrificial material are connected to each other, the method further comprising etching the sacrificial material at a predetermined position to isolate two adjacent lines of the sacrificial material.

18. The method of claim 16, further comprising removing selected lines of the sacrificial material before etching the uncovered portions of the layer stack.

19. The method of claim 18, wherein, after removing the hard mask lines, two adjacent lines of the sacrificial material are connected to each other, and wherein, by removing selected lines of the sacrificial material, pairs of lines of the sacrificial material are removed, the lines being connected with each other, the method further comprising etching the sacrificial material at a predetermined position so as to isolate two adjacent lines of the sacrificial material.

20. The method of claim 19, wherein removing selected lines of the sacrificial material and etching the line of the sacrificial material are performed by a simultaneous etching operation.

21. The method of claim 16, further comprising patterning the sacrificial layer to form pads of the sacrificial material, the pads being adjacent the lines of the sacrificial material.

22. The method of claim 21, wherein patterning the sacrificial layer to form pads of the sacrificial material comprises an etching operation for etching the sacrificial layer.

23. The method of claim 21, wherein the pads of the sacrificial material are defined such that two pads of the sacrificial material are disposed between two adjacent hard mask lines.

24. The method of claim 16, wherein the hard mask layer comprises silicon dioxide.

25. The method of claim 16, wherein the sacrificial material comprises silicon.

26. A method of forming an array of conductive lines, comprising:
providing a semiconductor substrate having a surface; and
providing a plurality of first conductive lines on the surface of the semiconductor substrate, the first conductive lines extending in a first direction;
wherein providing the plurality of first conductive lines comprises:
providing a layer stack comprising at least one conductive layer;
providing a hard mask layer and patterning the hard mask layer to form hard mask lines having sidewalls;
conformally depositing a sacrificial layer of a sacrificial material such that the deposited sacrificial layer has horizontal and vertical portions;
removing the horizontal portions of the sacrificial layer to form lines of the sacrificial material adjacent the sidewalls of the hard mask lines;
removing the hard mask lines to uncover portions of the layer stack; and
etching the uncovered portions of the layer stack, thereby forming single conductive lines.

27. The method of claim 26, wherein, after removing the hard mask lines, two adjacent lines of the sacrificial material are connected with each other, the method further comprising etching the sacrificial material at a predetermined position to isolate two adjacent lines of the sacrificial material.

28. The method of claim 26, further comprising patterning the sacrificial layer to form pads of the sacrificial material, the pads being adjacent the lines of the sacrificial material.

29. The method of claim 26, wherein patterning the sacrificial layer to form pads of the sacrificial material comprises an etching operation for etching the sacrificial layer.

30. The method of claim 29, wherein the etching operation for etching the sacrificial layer is performed by removing the horizontal portions of the sacrificial layer to form lines of the sacrificial material adjacent the sidewalls of the hard mask lines.

31. The method of claim 30, wherein the pads of the sacrificial material are defined such that two pads of the sacrificial material are disposed between two adjacent hard mask lines.

32. The method of claim 31, wherein the pads of the sacrificial material are defined in a final region of the array of conductive lines.

33. The method of claim 31, wherein all the pads of the sacrificial material are defined in a final region which is disposed on one side of the array of conductive lines.

34. The method of claim 31, wherein all the pads of the sacrificial material are defined in final regions which are disposed on opposite sides of the array of conductive lines.
